(19) United States
(12) Patent Application Publication
(10) Pub. No.: US 2019/0067638 A1
(43) Pub. Date: Feb. 28, 2019

(54) ENCAPSULATION LAYER STRUCTURE

(71) Applicant: CHUNGHWA PICTURE TUBES, LTD., Taoyuan City (TW)

(72) Inventors: Ching-Yu HUANG, Taoyuan City (TW); Ming-Hsiang LAI, Changhua County (TW); Ying-Hung CHUANG, Taoyuan City (TW); Yi-Fan NIU, Taipei City (TW); Wen-Cheng CHANG, Taichung City (TW)

(21) Appl. No.: 15/801,315

(22) Filed: Nov. 1, 2017

(30) Foreign Application Priority Data
Aug. 22, 2017 (CN) 201710723420.6

(51) Int. Cl. H01L 51/52; H01L 51/56

(52) U.S. Cl. CPC H01L 51/5256; H01L 2251/5338; H01L 2251/558; H01L 51/56

(57) ABSTRACT

The present invention discloses an encapsulation layer structure including a first organic layer, an inorganic thin film, and a second organic layer. The first organic layer has a bottom surface and a first wavy surface opposite to the bottom surface. The first wavy surface has a plurality of peak portions and a plurality of valley portions, and the peak portions and valley portions are alternately arranged with each other. The inorganic thin film is conformally disposed on the first wavy surface of the first organic layer, and the inorganic thin film has a second wavy surface opposite to the first wavy surface. The second organic layer is over the second wavy surface of the inorganic thin film. This encapsulation layer structure may prevent the penetration of oxygen and moisture effectively.

### CROSS-REFERENCE TO RELATED APPLICATION

This application claims priority to China Application Serial Number 201710723420.6, filed Aug. 22, 2017, which is herein incorporated by reference.

### BACKGROUND

### Field of Invention

The present invention relates to an encapsulation layer structure. More particularly, the present invention relates to a flexible encapsulation layer structure which is competent to reduce the stress on the encapsulation layer during bending and effectively prevent oxygen and moisture penetration.

### Description of Related Art

Compared with liquid crystal display (LCD) devices, organic light-emitting diode (OLED) display devices have faster response time, larger viewing angles, higher contrast, lighter weight, and lower power; meanwhile, it may conform to flexible substrates, such that it is recently in the limelight in display applications. Apart from organic materials for OLEDs, various polymeric materials have been developed for the small molecule flexible organic light emitting diode (FOLED) and the polymer light-emitting diode (PLED) displays. Numerous organic materials and polymeric materials are applicable to the fabricating of complex multilayer devices on various substrates due to their flexibility, such that they are suitable for use in transparent multi-color displays, for example, flat panel display (FPD), electrically pumped organic laser and organic optical amplifier.

As shown in FIG. 1A, an encapsulation layer structure 100 includes a first organic layer 110, an inorganic thin film 120 and a second organic layer 130. The first organic layer 110 has two substantially planar opposing surfaces. In some embodiments, the materials of the first organic layer 110 may include an epoxy resin, an acrylic resin, a urethane acrylate resin, or the like, or a combination of at least two materials described above, but not limited thereto. Since the material forming the first organic layer 110 has excellent flexibility and resilience, the internal stress of the encapsulated electronic component (for example, an OLED element or the like) may be reduced. In some embodiments, the first organic layer 110 may be formed by using ink-jet printing processes, spin-coating processes, coating processes, chemical vapor deposition (CVD) processes or the like.

The inorganic thin film 120 is disposed on the planar surface of the first organic layer 110. In other words, the inorganic thin film 120 has two substantially planar opposing surfaces as well. In some embodiments, the materials of the inorganic thin film 120 may include silicon nitrides (SiNₓ), silicon oxides (SiOₓ), copper oxides (CuOₓ), iron oxides (FeOₓ), titanium oxides (TiOₓ), zinc selenides (ZnSeₓ), aluminium oxides (AlOₓ), or a combination of at least two materials described above, but not limited thereto. Since the material constituting the inorganic thin film 120 has good compactness, it performs well in preventing the penetration of moisture and oxygen. In some embodiments, the inorganic thin film 120 may be formed by using a CVD process, a sputtering process, an atomic layer deposition (ALD) process, a plasma enhanced chemical vapor deposition (PECVD) process, or the like.

The second organic layer 130 is disposed on the planar surface of the inorganic thin film 120, such that the inorganic thin film 120 is between the first organic layer 110 and the second organic layer 130. In some embodiments, the material for forming the second organic layer 130 is the same as or similar to the material for forming the first organic layer 110. In some embodiments, the process of forming the second organic layer 130 may be substantially the same as or similar to the process of forming the first organic layer 110.

FIG. 1B shows the finite element analysis model of the encapsulation layer structure 100 described above. The General-purpose finite element software is applied to simulate the bending of the encapsulation layer structure 100 of the embodiment described above. When the encapsulation layer structure 100 illustrated in FIG. 1A occurs a bending deformation due to an external force, since the forming material of the inorganic thin film 120 is harder and more brittle than the forming material of the first organic layer 110 and the second organic layer 130, the center of the inorganic thin film 120 of the encapsulation layer structure 100 is subjected to a maximum stress of about 2300 Mpa, and the stress decreases from the center to both sides of the inorganic thin film 120.

The largest problem of current OLED is its short service life. The most influencing factor of the service life of the OLED is that moisture and oxygen in the air may penetrate into the OLED and react with the organic materials or the polymeric materials, resulting in the degradation of the organic materials or the polymeric materials and the formation of non-emissive dark spots, leading to a reduction of brightness, a rise of driving voltage, short circuit and a formation of black spots. Bending of a flexible OLED is frequently encountered, and it is prone to be fractured due to an external stress, resulting in penetration of moisture and oxygen. Accordingly, there is a need for an encapsulation layer structure which may reduce the stress of the encapsulation layer during bending.

### SUMMARY

A purpose of the present invention is to provide an encapsulation layer structure which is competent to reduce the stress on the encapsulation layer during bending.

To achieve the purpose described above, the present invention provides an encapsulation layer structure which includes a first organic layer, an inorganic thin film, and a second organic layer. The first organic layer has a bottom surface and a first wavy surface opposite to the bottom surface. The first wavy surface includes a plurality of peak portions and a plurality of valley portions, in which the peak portions and valley portions are alternately arranged with each other. The inorganic thin film is conformally disposed on the first wavy surface of the first organic layer, and the inorganic thin film has a second wavy surface opposite to the first wavy surface. The second organic layer is over the second wavy surface of the inorganic thin film.

According to some embodiments of the present invention, each of the first organic layer and the second organic layer has a thickness ranged from 1 micrometer (μm) to 30 μm.

According to some embodiments of the present invention, the inorganic thin film has a thickness ranged from 50 angstrom (Å) to 10000 Å.

According to some embodiments of the present invention, a height difference between each peak portion and each valley portion ranges from 1 μm to 20 μm.

According to some embodiments of the present invention, a spacing interval between adjacent ones of the peak portions ranges from 1 μm to 10000 μm.

Another purpose of the present invention is to provide an encapsulation layer structure which includes a first organic layer, a first inorganic thin film, a second organic layer, a second inorganic thin film, and a third organic layer. The first organic layer has a bottom surface and a first wavy surface opposite to the bottom surface. The first wavy surface includes a plurality of first peak portions and a plurality of first valley portions, while the first peak portions and the first valley portions are alternately arranged with each other. The first inorganic thin film is conformally disposed on the first wavy surface of the first organic layer, while the first inorganic thin film has a second wavy surface opposite to the first wavy surface. The second organic layer is disposed on the second wavy surface of the first inorganic thin film, while the second organic layer has a third wavy surface opposite to the second wavy surface. The second inorganic thin film is conformally disposed on the third wavy surface of the second organic layer, while the second inorganic thin film has a fourth wavy surface opposite to the third wavy surface. The third organic layer is over the fourth wavy surface of the second inorganic thin film.

According to some embodiments of the present invention, each of the first organic layer, the second organic layer, and the third organic layer has a thickness ranged from 1 μm to 30 μm.

According to some embodiments of the present invention, each of the first inorganic thin film and the second inorganic thin film has a thickness ranged from 50 Å to 10000 Å.

According to some embodiments of the present invention, a height difference between each of the first peak portion and the first valley portion ranges from 1 μm to 20 μm.

According to some embodiments of the present invention, a spacing interval between ones of the first peak portions ranges from 1 μm to 10000 μm.

According to some embodiments of the present invention, the third wavy surface has a plurality of second peak portions and a plurality of second valley portions, in which a height difference between each of the second peak portions and each of the second valley portion ranges from 1 μm to 20 μm.

According to some embodiments of the present invention, a spacing interval between adjacent ones of the second peak portions ranges from 1 μm to 10000 μm.

Compared with the prior art, the encapsulation layer structure of the present invention is competent to reduce the stress on the encapsulation layer during bending, while it may prevent the penetration of oxygen and moisture effectively.

### BRIEF DESCRIPTION OF THE DRAWINGS

FIG. 1A illustrates a schematic cross-sectional view of an encapsulation layer structure according to a comparative example of the present invention.

FIG. 1B illustrates a finite element analysis model of an encapsulation layer structure according to a comparative example of the present invention.

FIG. 2A illustrates a schematic cross-sectional view of an encapsulation layer structure according to one embodiment of the present invention.

FIG. 2B illustrates a finite element analysis model of an encapsulation layer structure according to one embodiment of the present invention.

FIG. 3 illustrates a schematic cross-sectional view of an encapsulation layer structure according to another embodiment of the present invention.

FIG. 4A and FIG. 4B illustrate schematic top views of a first organic layer according to some other embodiments of the present invention.

FIG. 5A to FIG. 5C illustrate schematic top views of an encapsulation layer structure according to the present invention.

FIG. 6 to FIG. 8 illustrate schematic cross-sectional views of an encapsulation layer structure at various fabrication stages according to some embodiments of the present invention.

### DETAILED DESCRIPTION

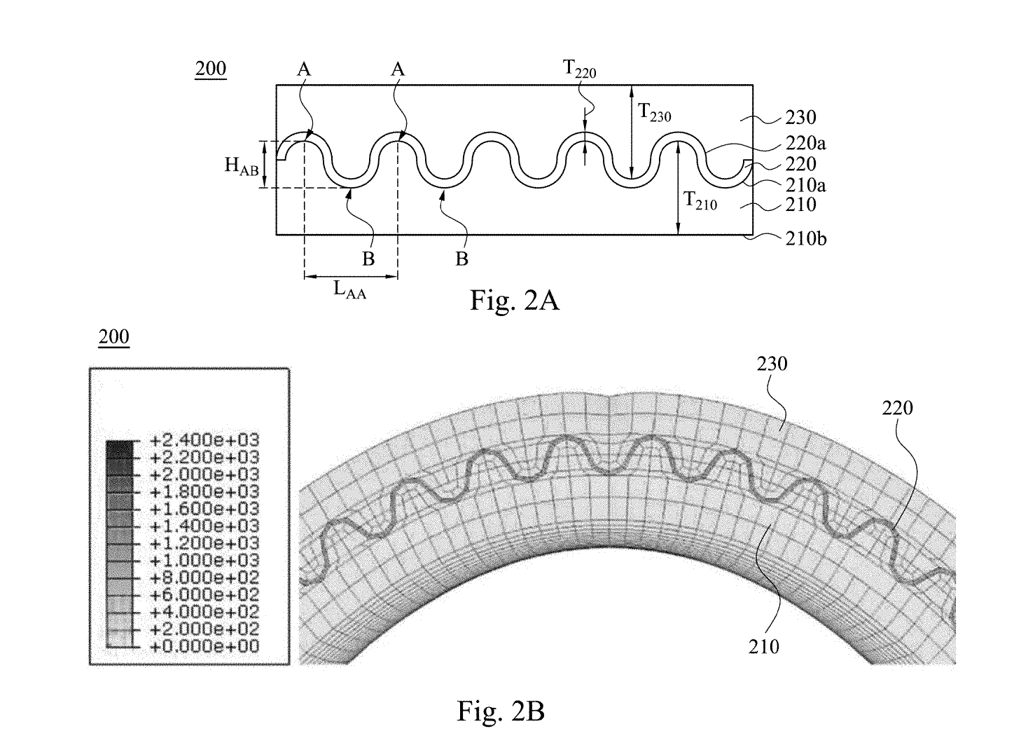

Please refer to FIG. 2A. FIG. 2A illustrates a schematic cross-sectional view of an encapsulation layer structure 200 according to one embodiment of the present invention. As shown in FIG. 2A, the encapsulation layer structure 200 includes a first organic layer 210, an inorganic thin film 220, and a second organic layer 230. The first organic layer 210 has a bottom surface 210b and a first wavy surface 210a opposite to the bottom surface 210b. It is noted that the bottom surface 210b is substantially a planar surface, whereas the first wavy surface 210a is wavy-shaped. In some embodiments, the first wavy surface 210a has a plurality of peak portions A and a plurality of valley portions B. The first wavy surface 210a is substantially a wavy undulating surface formed by the peak portions A and the valley portions B alternately arranged with each other. The cross-sectional profile of each peak portion A or each valley portion B may be, for example, a semicircular shape, a curved shape, a sinusoidal wave shape, or a combination thereof. The peak portion A and valley portion B respectively have a crest and a trough. Specifically, there is a height difference H_{AB} between adjacent crest and trough, and H_{AB} is ranged from 1 μm to 20 μm. According to various examples, when the height difference H_{AB} is greater than a certain value, such as 20 μm, it is implied that more organic material is required subsequently to fill the height difference H_{AB}, which leads to an increase in cost. In contrast, when the height difference H_{AB} is smaller than a certain value, such as 1 μm, the wave surface is unobvious, and the bending result is substantially similar to the comparative example described above, that is, fails to effectively reduce the stress on the encapsulation layer structure during bending. Therefore, the height difference H_{AB} may be, for example, 2 μm, 4 μm, 6 μm, 8 μm, 10 μm, 12 μm, 14 μm, 16 μm or 18 μm. Furthermore, there is a spacing L_{AA} between any two adjacent peak portions A, and L_{AA} is ranged from 1 μm to 10000 μm. According to various examples, when the spacing L_{AA} is greater than a certain value, such as 10000 μm, the wave surface is unobvious, and the bending result is substantially similar to the comparative example described above. In contrast, when the spacing L_{AA} is smaller than a certain value, such as 1 μm, the complexity of the fabricating process is increased. Therefore, the spacing L_{AA} may be, for example, 10 μm, 100 μm, 200 μm, 300 μm, 400 μm, 500 μm, 600 μm, 700 μm, 800 μm, 900 μm, 1000 μm, 2000 μm, 3000 μm, 4000 μm, 5000 μm, 6000 μm, 7000 μm, 8000 μm or 9000 μm.

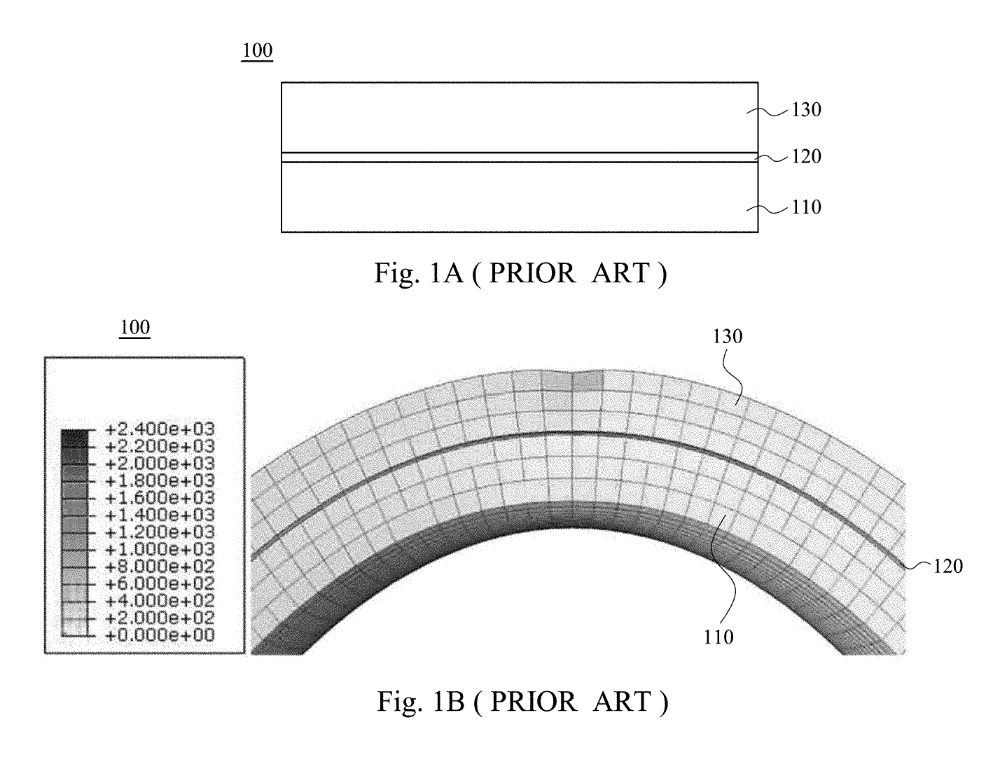

In some embodiments, the first organic layer 210 has a thickness T₂₁₀, and T₂₁₀ is ranged from 1 μm to 30 μm. According to various examples, when the thickness T₂₁₀ is greater than a certain value, such as 30 μm, the total thickness of the encapsulation layer structure 300 is increased, resulting in an increase in fabrication cost. In contrast, when the thickness T₂₁₀ is smaller than a certain value, such as 1 μm, the overall mechanical strength of the encapsulation layer structure 300 may be insufficient. Therefore, the thickness T₂₁₀ may be, for example, 5 μm, 8 μm, 10 μm, 15 μm, 20 μm or 25 μm. In some embodiments, the material of the first organic layer 210 may be substantially the same as or similar to that of the first organic layer 110 illustrated in FIG. 1A, and therefore is not repeated herein. In one example, the first organic layer 210 is formed by using ink-jet printing processes. In some embodiments, the process of forming the first organic layer 210 may be substantially the same as or similar to the process of forming the first organic layer 110 illustrated in FIG. 1A, and therefore is not repeated herein.

The inorganic thin film 220 is conformally disposed on the first wavy surface 210a of the first organic layer 210, and the inorganic thin film 220 has a second wavy surface 220a opposite to the first wavy surface 210a. In other words, the second wavy surface 220a of the inorganic thin film 220 has a wavy shape corresponding to the first wavy surface 210a. In some embodiments, the inorganic thin film 220 has a thickness T₂₂₀, which is ranged from 50 Å to 10000 Å. According to various examples, when the thickness T₂₂₀ is greater than a certain value, such as 10000 Å, the inorganic thin film 220 is prone to be fractured due to an external stress. In contrast, when the thickness T₂₂₀ is smaller than a certain value, such as 50 Å, the performance in preventing moisture and oxygen is poor. Therefore, the thickness T₂₂₀ may be, for example, 50 Å, 100 Å, 200 Å, 300 Å, 400 Å, 500 Å, 600 Å, 700 Å, 800 Å, 900 Å, 1000 Å, 1500 Å, 2000 Å, 3000 Å, 4000 Å, 5000 Å, 6000 Å, 7000 Å, 8000 Å or 9000 Å. In some embodiments, the material for forming the inorganic thin film 220 may be substantially the same as or similar to the material for forming the inorganic thin film 120 in FIG. 1A, and therefore is not repeated herein. In some embodiments, the process of forming the inorganic thin film 220 may be substantially the same as or similar to the process of forming the inorganic thin film 120 in FIG. 1A, and therefore is not repeated herein.

The second organic layer 230 is over the second wavy surface 220a of the inorganic thin film 220. In detail, the second organic layer 230 has a top surface opposite to the second wavy surface 220a, and the top surface is a planar surface. In some embodiments, the second organic layer 230 has a thickness T₂₃₀, and T₂₃₀ is ranged from 1 μm to 30 μm. According to various examples, when the thickness T₂₃₀ is greater than a certain value, such as 30 μm, the total thickness of the encapsulation layer structure 300 is increased, resulting in an increase in fabrication cost. In contrast, when the thickness T₂₃₀ is smaller than a certain value, such as 1 μm, the overall mechanical strength of the encapsulation layer structure 300 may be insufficient. The thickness T₂₁₀ may be, for example, 5 μm, 8 μm, 10 μm, 15 μm, 20 μm or 25 μm. In some embodiments, the material for forming the second organic layer 230 may be substantially the same as or similar to the material for forming the first organic layer 110 in FIG. 1A, and therefore is not repeated herein. In one example, the second organic layer 230 is formed by using an ink-jet printing process. In some embodiments, the process of forming the second organic layer 230 may be substantially the same as or similar to the process of forming the first organic layer 110 in FIG. 1A, and therefore is not repeated herein.

FIG. 2B illustrates a finite element analysis model of the encapsulation layer structure 200 described above. The General-purpose finite element software is applied to simulate the bending of the encapsulation layer structure 200 of the embodiment described above. When the encapsulation layer structure 20 illustrated in FIG. 2A is subjected to the same external force as the encapsulation layer structure 100 illustrated in FIG. 1B, the center of the inorganic thin film 220 is subjected to a stress of about 900 Mpa only since the inorganic thin film 220 in the encapsulation layer structure 200 is wavy-shaped. The stress on the center of the inorganic thin film 220 is substantially the same as the stress on the two sides of the inorganic thin film 220. Therefore, the encapsulation layer structure according to the embodiments of the present invention is competent to reduce the stress during bending.

The encapsulation layer structure 200 has the following advantages compared with the encapsulation layer structure 100: significantly increasing the flexibility of the encapsulation layer structure 200 and reducing the risk of fracture of the inorganic thin film during bending. By applying the encapsulation layer structure 200 in the encapsulation process of flexible OLED, the penetration of the moisture and oxygen from the air into the encapsulation layer structure through the generated cracks may further be avoided. The penetrated moisture and oxygen would react with the organic materials, and that leads to some drawbacks, such as a decrease in the brightness of the OLED elements, a rise in driving voltage, a short circuit of the internal element, and black spot. Therefore, for OLED elements, the encapsulation layer structure 200 provides longer service life as compared with the encapsulation layer structure 100.

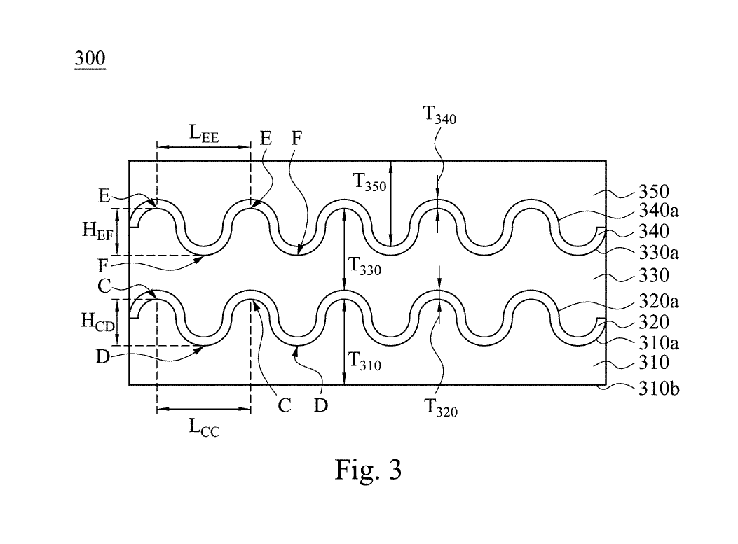

Please refer to FIG. 3. FIG. 3 illustrates a schematic cross-sectional view of an encapsulation layer structure 300 according to another embodiment of the present invention. As shown in FIG. 3, the encapsulation layer structure 300 includes a first organic layer 310, a first inorganic thin film 320, a second organic layer 330, a second inorganic thin film 340 and a third organic layer 350. The first organic layer 310 has a bottom surface 310b and a first wavy surface 310a opposite to the bottom surface 310b. It is noted that the bottom surface 310b is a substantially planar surface, whereas the first wavy surface 310a is wavy-shaped. In some embodiments, the first wavy surface 310a has a plurality of peak portions C and a plurality of valley portions D. The first wavy surface 310a is substantially a wavy undulating surface formed by the peak portions C and the valley portions D alternately arranged with each other. The cross-sectional profile of each peak portion C or each valley portion D may be, for example, a semicircular shape, a curved shape, a sinusoidal wave shape, or a combination thereof. The peak portion C and valley portion D respectively have a crest and a trough. Specifically, there is a height difference H_{CD} between adjacent crest and trough, and H_{CD} is ranged from 1 μm to 20 μm. According to various examples, when the height difference H_{CD} is greater than a certain value, such as 20 μm, it is implied that more organic material is required subsequently to fill the height difference H_{CD}, which leads to an increase in cost. In contrast, when the height difference H_{CD} is smaller than a certain value such as 1 μm, the wave surface is unobvious, and the bending result is substantially similar to the comparative example described above, that is, fails to effectively reduce the stress on the encapsulation layer structure during bending. Therefore, the height difference H_{CD} may be, for example, 2 μm, 4 μm, 6 μm, 8 μm, 10 μm, 12 μm, 14 μm, 16 μm or 18 μm. Furthermore, there is a spacing interval L_{CC} between any two adjacent peak portions C, and L_{CC} is ranged from 1 μm to 10000 μm. According to various examples, when the spacing interval L_{CC} is greater than a certain value such as 10000 μm, the wave surface is unobvious, and the bending result is substantially similar to the comparative example described above. In contrast, when the spacing interval L_{CC} is smaller than a certain value such as 1 μm, the complexity of the process is increased. Therefore, the spacing interval L_{CC} may be, for example, 10 μm, 100 μm, 200 μm, 300 μm, 400 μm, 500 μm, 600 μm, 700 μm, 800 μm, 900 μm, 1000 μm, 2000 μm, 3000 μm, 4000 μm, 5000 μm, 6000 μm, 7000 μm, 8000 μm or 9000 μm. In some embodiments, the first organic layer 310 has a thickness T₃₁₀, which ranges from 1 μm to 30 μm. According to various examples, when the thickness T₃₁₀ is greater than a certain value, such as 30 μm, the total thickness of the encapsulation layer structure 300 is increased, resulting in an increase in fabrication cost. In contrast, when the thickness T₃₁₀ is smaller than a certain value, such as 1 μm, the overall mechanical strength of the encapsulation layer structure 300 may be insufficient. Therefore, the thickness T₃₁₀ may be, for example, 5 μm, 8 μm, 10 μm, 15 μm, 20 μm or 25 μm. In some embodiments, the material for forming the first organic layer 310 may be substantially the same as or similar to the material for forming the first organic layer 110 in FIG. 1A, and therefore is not repeated herein. In one example, the first organic layer 310 is formed by using an ink-jet printing process. In some embodiments, the process of forming the first organic layer 310 may be substantially the same as or similar to the process of forming the first organic layer 110 in FIG. 1A, and therefore is not repeated herein.

The first inorganic thin film 320 is conformally disposed on the first wavy surface 310a of the first organic layer 310, and the first inorganic thin film 320 has a second wavy surface 320a opposite to the first wavy surface 310a. In other words, the second wavy surface 320a of the first inorganic thin film 320 has a wavy-shaped corresponding to the first wavy surface 310a. In some embodiments, the first inorganic thin film 320 has a thickness T₃₂₀, which is ranged from 50 Å to 10000 Å. According to various examples, when the thickness T₃₂₀ is greater than a certain value, such as 10000 Å, the first inorganic thin film 320 is prone to be fractured due to an external stress. In contrast, when the thickness T₃₂₀ is smaller than a certain value, such as 50 Å, the performance in preventing moisture and oxygen is poor. Therefore, the thickness T₃₂₀ may be, for example, 50 Å, 100 Å, 200 Å, 300 Å, 400 Å, 500 Å, 600 Å, 700 Å, 800 Å, 900 Å, 1000 Å, 1500 Å, 2000 Å, 3000 Å, 4000 Å, 5000 Å, 6000 Å, 7000 Å, 8000 Å or 9000 Å. In some embodiments, the material for forming the first inorganic thin film 320 may be substantially the same as or similar to the material for forming the inorganic thin film 120 in FIG. 1A, and therefore is not repeated herein. In some embodiments, the process of forming the first inorganic thin film 320 may be substantially the same as or similar to the process of forming the inorganic thin film 120 in FIG. 1A, and therefore is not repeated herein.

The second organic layer 330 is disposed on the second wavy surface 320a of the first inorganic thin film 320, and the second organic layer 330 has a third wavy surface 330a opposite to the second wavy surface 320a. Various aspects of the third wavy surface 330a (for example, a spacing interval between two adjacent peaks, a height difference between peak portion and valley portion, and else) may be the same as, similar to, or different from the first wavy surface 310a. In some embodiments, the third wavy surface 330a has a plurality of peak portions E and a plurality of valley portions F. The third wavy surface 330a is substantially a wavy undulating surface formed by a plurality of peak portions E and a plurality of valley portions F alternately arranged with each other. The cross-sectional profile of each peak portion E or each valley portion F may be, for example, a semicircular shape, a curved shape, a sinusoidal wave shape, or a combination thereof. The peak portion E and valley portion F respectively have a crest and a trough. Specifically, there is a height difference H_{EF} between adjacent crest and trough, and H_{EF} is ranged from 1 μm to 20 μm. According to various examples, when the height difference H_{EF} is greater than a certain value, such as 20 μm, it is implied that more organic material is required subsequently to fill the height difference H_{EF}, which leads to an increase in cost. In contrast, when the height difference H_{EF} is smaller than a certain value, such as 1 μm, the wave surface is unobvious, and the bending result is substantially similar to the comparative example described above, that is, fails to effectively reduce the stress on the encapsulation layer structure during bending. Therefore, the height difference H_{EF} may be, for example, 2 μm, 4 μm, 6 μm, 8 μm, 10 μm, 12 μm, 14 μm, 16 μm or 18 μm. Furthermore, there is a spacing interval L_{EE} between two adjacent peak portions E, L_{EE} is ranged from 1 μm to 10000 μm. According to various examples, when the spacing interval L_{EE} is greater than a certain value, such as 10000 μm, the wave surface is unobvious, and the bending result is substantially similar to the comparative example described above. In contrast, when the spacing interval L_{EE} is smaller than a certain value, such as 1 μm, the complexity of the process is increased. Therefore, the spacing interval L_{EE} may be, for example, 10 μm, 100 μm, 200 μm, 300 μm, 400 μm, 500 μm, 600 μm, 700 μm, 800 μm, 900 μm, 1000 μm, 2000 μm, 3000 μm, 4000 μm, 5000 μm, 6000 μm, 7000 μm, 8000 μm or 9000 μm. In some embodiments, the second organic layer 330 has a thickness T₃₃₀, T₃₃₀ is ranged from 1 μm to 30 μm. According to various examples, when the thickness T₃₃₀ is greater than a certain value, such as 30 μm, the total thickness of the encapsulation layer structure 300 is increased, resulting in an increase in fabrication cost. In contrast, when the thickness T₃₃₀ is smaller than a certain value, such as 1 μm, the overall mechanical strength of the encapsulation layer structure 300 may be insufficient. Therefore, the thickness T₃₃₀ may be, for example, 5 μm, 8 μm, 10 μm, 15 μm, 20 μm or 25 μm. In some embodiments, the material for forming the second organic layer 330 may be substantially the same as or similar to the material for forming the first organic layer 110 in FIG. 1A, and therefore is not repeated herein. In one example, the second organic layer 330 is formed by using ink-jet printing process. In some embodiments, the process of forming the second organic layer 330 may be substantially the same as or similar to the process of forming the first organic layer 110 in FIG. 1A, and therefore is not repeated herein.

The second inorganic thin film 340 is conformally disposed on the third wavy surface 330a of the second organic layer 330, and the second inorganic thin film 340 has a fourth wavy surface 340a opposite to the third wavy surface 330a. In other words, the fourth wavy surface 340a of the second inorganic thin film 340 has a wavy shape corresponding to the third wavy surface 330a. In some embodiments, the second inorganic thin film 340 has a thickness T₃₄₀, which ranges from 50 Å to 10000 Å. According to various examples, when the thickness T₃₄₀ is greater than a certain value, such as 10000 Å, the second inorganic thin film 340 is prone to be fractured due to an external stress. In contrast, when the thickness T₃₄₀ is smaller than a certain value, such as 50 Å, the performance in preventing moisture and oxygen is poor. Therefore, the thickness T₃₄₀ may be, for example, 50 Å, 100 Å, 200 Å, 300 Å, 400 Å, 500 Å, 600 Å, 700 Å, 800 Å, 900 Å, 1000 Å, 1500 Å, 2000 Å, 3000 Å, 4000 Å, 5000 Å, 6000 Å, 7000 Å, 8000 Å or 9000 Å. In some embodiments, the material for forming the second inorganic thin film 340 may be substantially the same as or similar to the material for forming the inorganic thin film 120 in FIG. 1A, and therefore is not repeated herein. In some embodiments, the process of forming the second inorganic thin film 340 may be substantially the same as or similar to the process of forming the inorganic thin film 120 in FIG. 1A, and therefore is not repeated herein.

The third organic layer 350 is over the fourth wavy surface 340a of the second inorganic thin film 340. In detail, the third organic layer 350 has a top surface opposite to the fourth wavy surface 340a, and the top surface is a planar surface. In some embodiments, the third organic layer 350 has a thickness T₃₅₀, which ranges from 1 μm to 30 μm. According to various examples, when the thickness T₃₅₀ is greater than a certain value, such as 30 μm, the total thickness of the encapsulation layer structure 300 is be increased, resulting in an increase in fabrication cost. In contrast, when the thickness T₃₅₀ is smaller than a certain value, such as 1 μm, the overall mechanical strength of the encapsulation layer structure 300 may be insufficient. Therefore, the thickness T₃₅₀ may be, for example, 5 μm, 8 μm, 10 μm, 15 μm, 20 μm or 25 μm. In some embodiments, the material for forming the third organic layer 350 may be substantially the same as or similar to the material for forming the first organic layer 110 in FIG. 1A, and therefore is not repeated herein. In one example, the third organic layer 350 is formed by using ink-jet printing process. In some embodiments, the process of forming the third organic layer 350 may be substantially the same as or similar to the process of forming the first organic layer 110 in FIG. 1A, and therefore is not repeated herein.

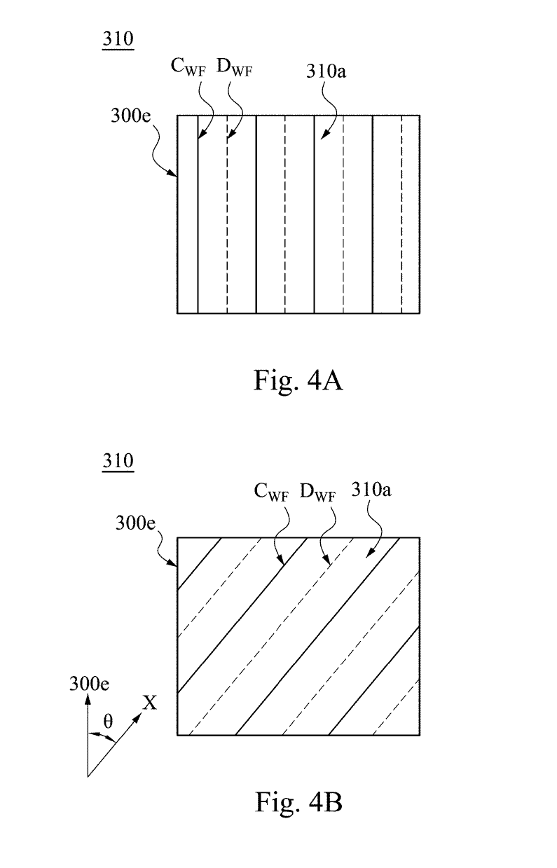

FIG. 4A and FIG. 4B illustrate schematic top views of a first organic layer 310 according to yet some embodiments of the present invention. The solid line (C_{WF}) in FIG. 4A and FIG. 4B represents the connection line of continuously adjacent crests of the first wavy surface 310a (i.e., wavefront), while the dashed line (D_{WF}) represents the connection line of continuously adjacent troughs of the first wavy surface 310a, the connection line C_{WF} of crests and the connection line D_{WF} of troughs are substantially parallel to each other, thereby forming a corrugated array. The connection line C_{WF} of crests extends from one edge of the first organic layer 310 to another edge of the first organic layer 310. For example, as shown in FIG. 4A, the angle between the edge 300e of the first organic layer 310 and each of the connection line C_{WF} of crests and/or the connection line D_{WF} of troughs may be 0 degrees (or 90 degrees). That is, the edge 300e of the first organic layer 310 is substantially parallel (or perpendicular) to the connection line C_{WF} of crests and/or the connection line D_{WF} of troughs. Furthermore, as shown in FIG. 4B, the connection line C_{WF} of crests and/or the connection line D_{WF} of troughs may extend along a first direction X, and an angle θ is formed between the edge 300e of the first organic layer 310 and each of the connection line C_{WF} of crests and/or the connection line D_{WF} of troughs, in which the angle θ may be any degree. In some examples, the angle θ may be ranged from 35 degrees to 55 degrees, for example, 37 degrees, 39 degrees, 41 degrees, 43 degrees, 45 degrees, 47 degrees, 49 degrees, 51 degrees or 53 degrees. It is to be understood that the schematic top view of the third wavy surface 330a may be the same as or similar to the schematic top view of the first wavy surface 310a described above.

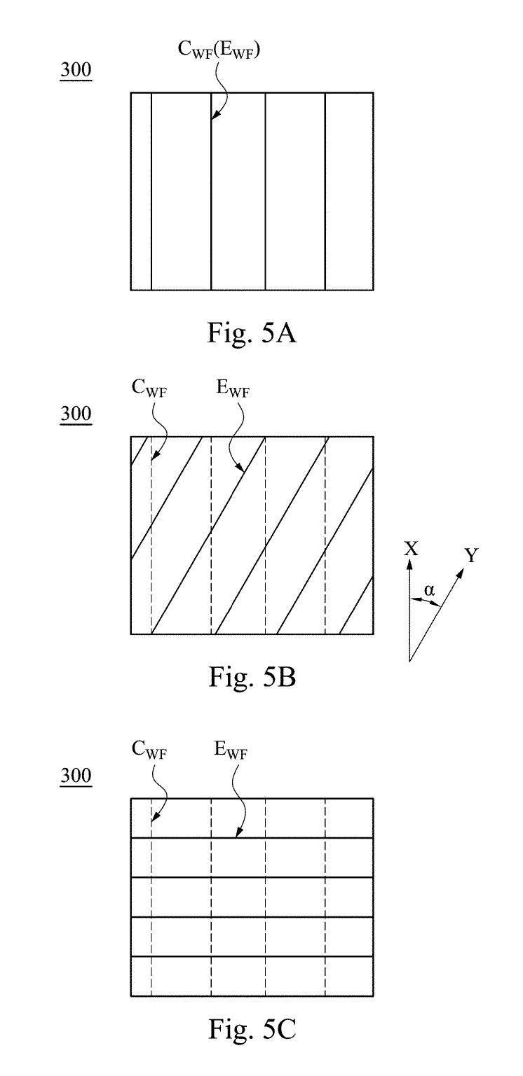

FIG. 5A to FIG. 5C illustrate schematic top views of the encapsulation layer structure 300 according to yet some embodiments of the present invention. The dashed line (C_{WF}) in FIG. 5A to FIG. 5C represents the connection line of continuously adjacent crests of the first wavy surface 310a (labeled in FIG. 3), while the solid line (E_{WF}) represents the connection line of continuously adjacent crests of the third wavy surface 330a (labeled in FIG. 3). In some embodiments, as shown in FIG. 5 Å, the connection line C_{WF} of crests of the first wavy surface 310a and the connection line E_{WF} of crests of the third wavy surface 330a are overlapped to each other (or parallel). In some other embodiments, as shown in FIG. 5B, the connection line C_{WF} of crests of the first wavy surface 310a extends along the first direction X, while the connection line E_{WF} of crests of the third wavy surface 330a extends along the second direction Y. An angle α is formed between the connection line C_{WF} of crests of the first wavy surface 310a and the connection line E_{WF} of crests of the third wavy surface 330a, in which the angle α may be any degree. In some examples, the angle α may be ranged from 35 degrees to 55 degrees, for example, 37 degrees, 39 degrees, 41 degrees, 43 degrees, 45 degrees, 47 degrees, 49 degrees, 51 degrees or 53 degrees. In some other embodiments, as shown in FIG. 5C, the connection line C_{WF} of crests of the first wavy surface 310a and the connection line E_{WF} of crests of the third wavy surface 330a are perpendicular to each other.

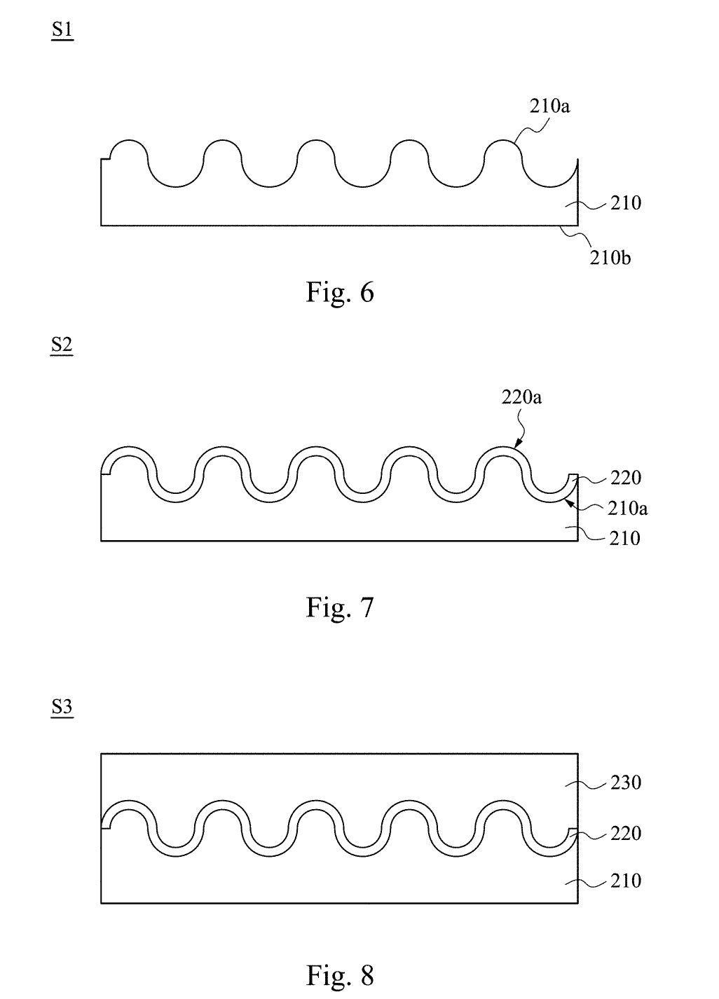

FIG. 6 to FIG. 8 are cross-sectional views schematically illustrating a method of fabricating an encapsulation layer structure at various fabrication stages according to some embodiments of the present invention. As shown in FIG. 6, in the method of fabricating the encapsulation layer structure 200, step S1 is the formation of a first organic layer 210 using an ink-jet printing process. Compared with traditional vapor deposition process, the ink-jet printing process may significantly reduce production costs and improve the efficiency of the use of materials. Specifically, in step S1, a liquid organic material is first sprayed onto an electronic component (not shown) or a substrate (not shown) through an ink jet head in an ink-jet printing apparatus to accumulate an organic material having a certain thickness. A UV curing treatment or a heat curing treatment is performed to cure or harden the organic material. Subsequently, the resolution of the ink-jet printing apparatus is adjusted to form an undulating wave surface. A UV curing treatment or a heat curing treatment is performed once again to cure or harden the organic material having the undulating wave surface, thereby forming the first organic layer 210. Various features of the first organic layer 210 have been described above and are not repeatedly described herein.

As shown in FIG. 7, in the method of fabricating the encapsulation layer structure 200, step S2 is the conformal deposition of the inorganic thin film 220 on the first wavy surface 210a of the first organic layer 210 using CVD, sputtering, ALD, PECVD or similar processes. It is to be understood that various features of the inorganic thin film 220 have been described above and are not repeatedly described herein. Therefore, the second wavy surface 220a of the inorganic thin film 220 has a wavy-shaped corresponding to the first wavy surface 210a by using the process of conformal deposition.

As shown in FIG. 8, in the method of fabricating the encapsulation layer structure 200, step S3 is the formation of the second organic layer 230 by using an ink-jet printing process. In detail, a liquid organic material is first sprayed onto the inorganic thin film 220 through an ink jet head in an ink-jet printing apparatus, with the organic material may completely fill the valley portions B in the second wavy surface 220a and further cover the peak portions A of the second wavy surface 220a to form a planar surface. Finally, the second organic layer 230 is cured by UV curing or thermal curing processes. It is to be understood that the various features of the second organic layer 230 have been described above and are not repeatedly described herein. In addition, steps S1, S2, and S3 may be repeated to form the encapsulation layer structure 300 as shown in FIG. 3.

Although the present invention has been described in considerable detail with reference to certain embodiments thereof, other embodiments are possible. Therefore, the spirit and scope of the appended claims should not be limited to the description of the embodiments contained herein.

What is claimed is:

1. An encapsulation layer structure, comprising:
a first organic layer having a bottom surface and a first wavy surface opposite to the bottom surface, the first wavy surface comprising a plurality of peak portions and a plurality valley portions, wherein the peak portions and the valley portions are alternately arranged with each other;
an inorganic thin film conformally disposed on the first wavy surface of the first organic layer, the inorganic thin film having a second wavy surface opposite to the first wavy surface; and
a second organic layer on the second wavy surface of the inorganic thin film.

2. The encapsulation layer structure of claim 1, wherein each of the first organic layer and the second organic layer has a thickness ranged from 1 micrometer (μm) to 30 μm.

3. The encapsulation layer structure of claim 1, wherein the inorganic thin film has a thickness ranged from 50 angstrom (Å) to 10000 Å.

4. The encapsulation layer structure of claim 1, wherein a height difference between each peak portion and each valley portion ranges from 1 μm to 20 μm.

5. The encapsulation layer structure of claim 1, wherein a spacing interval between adjacent ones of the peak portions ranges from 1 μm to 10000 μm.

6. An encapsulation layer structure, comprising:
a first organic layer having a bottom surface and a first wavy surface opposite to the bottom surface, the first wavy surface comprising a plurality of first peak portions and a plurality of first valley portions, wherein the first peak portions and the first valley portions are alternately arranged with each other;
a first inorganic thin film conformally disposed on the first wavy surface of the first organic layer, the inorganic thin film having a second wavy surface opposite to the first wavy surface;
a second organic layer disposed on the second wavy surface of the first inorganic thin film, the second organic layer having a third wavy surface opposite to the second wavy surface;
a second inorganic thin film conformally disposed on the third wavy surface of the second organic layer, the second inorganic thin film having a fourth wavy surface opposite to the third wavy surface; and
a third organic layer on the fourth wavy surface of the second inorganic thin film.

7. The encapsulation layer structure of claim 6, wherein each of the first organic layer, the second organic layer, and the third organic layer has a thickness ranged from 1 μm to 30 μm.

8. The encapsulation layer structure of claim 6, wherein each of the first inorganic thin film and the second inorganic thin film has a thickness ranged from 50 Å to 10000 Å.

9. The encapsulation layer structure of claim 6, wherein a height difference between each first peak portion and each first valley portion ranges from 1 μm to 20 μm.

10. The encapsulation layer structure of claim 9, wherein a spacing interval between adjacent ones of the first peak portions ranges from 1 μm to 10000 μm.

11. The encapsulation layer structure of claim 6, wherein the third wavy surface has a plurality of second peak portions and a plurality of second valley portions, wherein a height difference between each second peak portion and each second valley portion ranges from 1 μm to 20 μm.

12. The encapsulation layer structure of claim 11, wherein a spacing interval between adjacent ones of the second peaks ranges from 1 μm to 10000 μm.
